(19) United States
(12) Patent Application Publication
(10) Pub. No.: US 2024/0356559 A1
(43) Pub. Date: Oct. 24, 2024

(54) CONTINUOUS-TIME NOISE-SHAPING SAR ADC WITHOUT EXCESS LOOP DELAY

(71) Applicant: Samsung Electronics Co., Ltd., Suwon-si (KR)

(72) Inventors: Sein OH, Daejeon (KR); Minkyu JE, Daejeon (KR); Gichan YUN, Daejeon (KR)

(73) Assignees: Samsung Electronics Co., Ltd., Suwon-si (KR); KOREA ADVANCED INSTITUTE OF SCIENCE AND TECHNOLOGY, Daejeon (KR)

(21) Appl. No.: 18/421,425

(22) Filed: Jan. 24, 2024

(30) Foreign Application Priority Data
Apr. 20, 2023 (KR) 10-2023-0052230
Jun. 22, 2023 (KR) 10-2023-0080650

(51) Int. Cl. H03M 1/46

(52) U.S. Cl. CPC H03M 1/466; H03M 1/462

(57) ABSTRACT

An analog-to-digital converter includes a first input unit configured to quantize an input signal to generate a quantized input signal, a second input unit configured to generate a residue signal corresponding to a difference between the input signal and a previous digital value output during a previous analog-to-digital conversion cycle, a loop filter configured to generate an integrated residue signal, a comparator configured to output a digital value corresponding to the input signal in units of bits based on the quantized input signal and the integrated residue signal, and a controller configured to apply the previous digital value to the second input unit such that the residue signal is generated during quantization of the input signal and to control the first input unit such that the input signal is quantized in a successive approximation scheme based on an output of the comparator.

### CROSS-REFERENCE TO RELATED APPLICATION(S)

This U.S. non-provisional application claims priority under 35 USC § 119 to Korean Patent Application Nos. 10-2023-0052230, filed on Apr. 20, 2023 and 10-2023-0080650, filed on Jun. 22, 2023 in the Korean Intellectual Property Office, the disclosures of which are incorporated herein by reference in their entirety.

### BACKGROUND

Example embodiments relate to an analog-to-digital converter and/or a method of operating the same.

An analog-to-digital converter (ADC) is a device converting an analog signal into a digital signal. There are various types of ADCs depending on a method of converting an analog signal into a digital signal.

For example, a flash ADC operates in such a manner that a comparator is disposed at each quantization reference point and all comparators are configured to simultaneously operate for an analog input. A successive approximation register (SAR) ADC operates in a such a manner of continuously fining a digital value corresponding to analog input using a single comparator. On the other hand, a delta-sigma modulator (DSM) ADC has a characteristic structure using a loop filter for quantization noise shaping.

### SUMMARY

Some example embodiments provide a successive approximation register analog-to-digital converter, operating based on continuous time and having a delta-sigma modulator structure, and/or a method operating the same.

According to an example embodiment, an analog-to-digital converter includes a first input unit configured to quantize an input signal to generate a quantized input signal, a second input unit configured to generate a residue signal corresponding to a difference between the input signal and a previous digital value output during a previous analog-to-digital conversion cycle, a loop filter configured to integrate the generate an integrated residue signal, a comparator configured to output a digital value corresponding to the input signal in units of bits based on the quantized input signal and the integrated residue signal, and a controller configured to apply the previous digital value to the second input unit such that the residue signal is generated during quantization of the input signal and to control the first input unit such that the input signal is quantized in a successive approximation scheme based on an output of the comparator.

The first input unit may include a first input capacitor to which the input signal is applied, a first capacitor digital-to-analog converter (CDAC) connected to the first input capacitor, and a plurality of first switches configured to control an operation of the first CDAC. The second input unit may include a second input capacitor to which the input signal is applied, a second CDAC connected to the second input capacitor, and a plurality of second switches configured to control an operation of the second CDAC.

The input signal may be a continuous analog signal applied to each of the first and second input capacitors without an additional sampling operation.

The analog-to-digital conversion cycle of the analog-to-digital converter may include a quantization operation period, in which the input signal is quantized, and a reset operation period in which a next analog-to-digital conversion cycle is prepared. The residue signal may be continuously applied to the loop filter during the quantization operation period. The residue signal integrated in the loop filter may be continuously input to the comparator, together with the quantized input signal, during the quantization operation period.

The controller may control the plurality of first switches based on an output of the comparator to quantize the input signal through the first CDAC in the successive approximation scheme during the quantization operation period.

The controller may apply the previous digital value to the plurality of second switches to generate the residue signal through the second CDAC during the quantization operation period.

The controller may reset the plurality of first switches during the reset operation period and applies a digital value, output from the comparator, to the plurality of second switches during the quantization operation period.

The loop filter may include at least one of a GM-C integrator, a capacitively-coupled instrumentation amplifier (CCIA), or a circuit in which a GM-C integrator and a CCIA are combined with each other.

The input signal may be a differential input signal comprising a first input signal and a second input signal,
the first input unit comprises a first differential input unit configured to quantize the first input signal and a second differential input unit configured to quantize the second input signal, and
the second input unit comprises a third differential input unit configured to generate a first residue signal corresponding to a difference between the first input signal and the previous digital value and a fourth differential input unit configured to generate a second residue signal corresponding to a difference between the second input signal and the previous digital value.

The loop filter may integrate each of the first and second residue signals. The comparator may output a digital value corresponding to the differential input signal in units of bits based on the quantized first and second input signals and the integrated first and second residue signals. The controller may apply the previous digital value to the third and fourth differential input units, respectively, to generate the first and second residue signals during quantization of the first and second input signals, and may control the first and second differential input units, respectively, to quantize the first and second input signals in a successive approximation scheme based on an output of the comparator.

Each of the first and second CDACs may include at least one redundancy capacitor.

The analog-to-digital converter may correspond to a single stage, among a plurality of stages included in an analog-to-digital converter having a pipeline structure.

The analog-to-digital converter may include a delta-signal modulator having a nested structure.

According to an example embodiment, a method of operating an analog-to-digital converter includes performing a quantization operation on an input signal in a successive approximation scheme, integrating a residue signal generated while the quantization operation is performed, and outputting a digital value corresponding to the input signal based on an input signal quantized through the quantization operation and the integrated residue signal. The residue signal may correspond to a difference between the input signal and a previous digital value output during a previous analog-to-digital conversion cycle.

The analog-to-digital converter may include a first input unit and a second input unit, each to which the input signal is applied. The performing the quantization operation may include performing the quantization operation based on the input signal applied through the first input unit. The integrating the residue signal may include generating the residue signal based on the input signal applied through the second input unit and integrating the generated residue signal.

The input signal may be a continuous analog signal applied to each of the first and second input units without an additional sampling operation.

The first input unit may include a first input capacitor to which the input signal is applied, a first capacitor digital-to-analog converter (CDAC) connected to the first input capacitor, and a plurality of first switches configured to control an operation of the first CDAC. The second input unit may include a second input capacitor to which the input signal is applied, a second CDAC connected to the second input capacitor, and a plurality of second switches configured to control an operation of the second CDAC.

The outputting the digital value may include outputting a digital value corresponding to the input signal in units of bits. The performing the quantization operation may include controlling operations of the plurality of first switches based on the digital value output in units of bits to quantize the input signal in the successive approximation scheme. The generating the residue signal may include applying the previous digital value to the plurality of second switches to generate the residue signal while the quantization operation is performed.

The method may include resetting the plurality of first switches and applying the digital value corresponding to the input signal to the plurality of second switches when the digital value corresponding to the input signal is output in units of bits.

According to an example embodiment, a successive approximation analog-to-digital converter includes a first capacitively-coupled input unit configured to receive an input signal being a continuously changed analog signal and to quantize the input signal in a binary search scheme based on a control signal to generate a quantized input signal, a second capacitively-coupled input unit configured to receive the input signal and to generate a residue signal corresponding to a difference between the input signal and a previous digital value when the previous digital value is received, a loop filter configured to integrate the residue signal, a comparator configured to output a digital value corresponding to the input signal in units of bits based on the quantized input signal and the integrated residue signal, and a successive approximation register logic configured to apply the control signal to the first capacitively-coupled input unit based on an output of the comparator. The successive approximation register logic may apply the previous digital value, output from the comparator, to the second capacitively-coupled input unit during a previous analog-to-digital conversion cycle.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a block diagram illustrating an example of a configuration of an analog-to-digital converter according to an example embodiment.

FIG. 2A is a diagram illustrating an implementation example of an analog-to-digital converter according to an example embodiment.

FIG. 2B is a timing diagram illustrating an example of an analog-to-digital conversion cycle of the analog-to-digital converter of FIG. 2A.

FIG. 3 is a diagram illustrating the types of loop filters according to various example embodiments.

FIG. 4A is a diagram illustrating an operation of an analog-to-digital converter according to an example embodiment.

FIG. 4B is a diagram illustrating an operation of an analog-to-digital converter according to an example embodiment.

FIG. 4C is a diagram illustrating an operation of an analog-to-digital converter according to an example embodiment.

FIG. 5A is a block diagram of a general noise shaping SAR ADC operating based on continuous time.

FIG. 5B is an operation timing diagram for the general noise shaping SAR ADC of FIG. 5A.

FIG. 6A is a block diagram of an analog-to-digital converter according to an example embodiment.

FIG. 6B is a graph illustrating signal transfer characteristics and noise transfer characteristics of an analog-to-digital converter according to an example embodiment.

FIG. 7A is a block diagram in the case in which an analog-to-digital converter operating based on discrete time is applied to a continuous-time delta-sigma modulator.

FIG. 7B is an operation timing diagram of the analog-to-digital converter of FIG. 7A.

FIG. 8A is a block diagram of an analog-to-digital converter according to an example embodiment.

FIG. 8B is an operation timing diagram of the analog-to-digital converter of FIG. 8A.

FIG. 9 is a flowchart illustrating a method of operating an analog-to-digital converter according to an example embodiment.

FIG. 10 is a diagram illustrating an implementation example of an analog-to-digital converter according to an example embodiment.

FIG. 11 is a diagram illustrating an implementation example of an analog-to-digital converter according to an example embodiment.

FIG. 12 is a diagram illustrating an implementation example of an analog-to-digital converter according to an example embodiment.

### DETAILED DESCRIPTION

Hereinafter, example embodiments will be described with reference to the accompanying drawings.

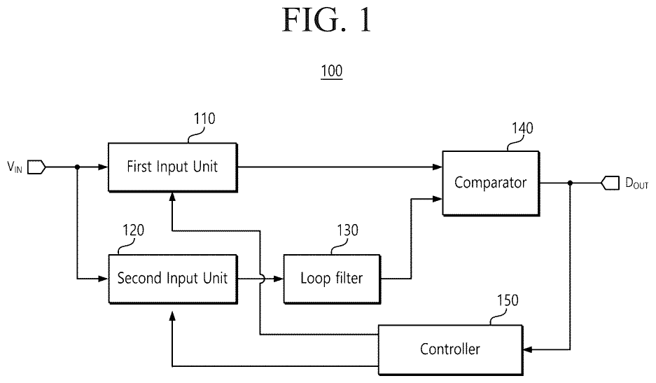

FIG. 1 is a block diagram illustrating an example of a configuration of an analog-to-digital converter 100 according to an example embodiment. Referring to FIG. 1, the analog-to-digital converter 100 may include a first input unit 110, a second input unit 120, a loop filter 130, a comparator 140, and a controller 150.

The first input unit 110 may receive an input signal V_{IN}, and may quantize the received input signal V_{IN} under the control of the controller 150. In this case, the input signal V_{IN} may be a continuous analog signal applied to the first input unit 110 without an additional sampling operation.

For example, the first input unit 110 may quantize the input signal V_{IN} using a successive approximation (SA) scheme under the control of the controller 150. The successive approximation scheme may be a technique for sequentially finding a digital value corresponding to the input signal V_{IN} from a most significant bit (MSB) to a least significant bit (LSB) based on binary search. The successive approximation scheme may be referred to as a successive approximation register (SAR) scheme.

The second input unit 120 may receive the input signal V_{IN}, and may generate a residue signal under the control of the controller 150. The residue signal may be a signal corresponding to a difference between the input signal V_{IN} and a previous digital value. The previous digital value refers to a digital value output from the analog-to-digital converter 100 during a previous analog-to-digital conversion cycle. The residue signal generated by the second input unit 120 may be provided to the loop filter 130.

The loop filter 130 may perform a noise shaping operation based on the residue signal. For example, the loop filter 130 may integrate the residue signal generated by the second input unit 120, and may provide the integrated residue signal to the comparator 140.

According to an example embodiment, the loop filter 130 may integrate residue signals continuously provided from the second input unit 120, and may continuously provide the integrated residue signals to the comparator 140.

The comparator 140 may output a digital value D_{OUT}, corresponding to the input signal V_{IN}, in units of bits based on the quantized input signal provided from the first input unit 110 and the integrated residue signal provided from the loop filter 130.

The controller 150 may control operations of the first input unit 110 and the second input unit 120 based on an output of the comparator 140.

For example, the controller 150 may control the first input unit 110 to quantize the input signal VIN using a successive approximation scheme, based on the output of the comparator 140. The input signal V_{IN} quantized by the first input unit 110 may be input to the comparator 140, and the comparator 140 may sequentially output a digital value corresponding to the input signal V_{IN} from an MSB to an LSB.

The controller 150 may control the second input unit 120 to generate a residue signal during quantization of the input signal V_{IN}. For example, the controller 150 may store the digital value output from the comparator 140 during a previous analog-to-digital conversion cycle. Accordingly, the controller 140 may apply a previous digital value to the second input unit 120 such that a residue signal is generated in the second input unit 120 while the input signal V_{IN} is being quantized in the first input unit 110. The residue signal generated in the second input unit 120 may be input to the loop filter 130 to be integrated, and the integrated residue signal may be input to the comparator 140 to be digitalized together with the quantized input signal.

In general, a noise shaping successive approximation register (SAR) analog-to-digital converter (ADC), operating based on continuous time, may perform a quantization operation on an input signal and an integration operation on a residue signal in series. Therefore, quantization operation time and integration operation time are respectively required within a single conversion cycle. In addition, the quantization operation time should be significantly shorter than the integration operation time so as to stabilize a system. As a result, a sampling rate and a bandwidth are limited.

However, as described above, according to an example embodiment, the analog-to-digital converter 100 may include the first input unit 110 for a quantization operation on the input signal V_{IN} and the second input unit 120 for a residue signal generation operation. Therefore, the analog-to-digital converter 110 may perform the quantization operation and a residue signal integration operation in parallel. In this case, a sampling rate of the analog-to-digital converter 100 is determined by time for which the quantization operation is performed, so that a higher sampling rate and a wider bandwidth may be achieved.

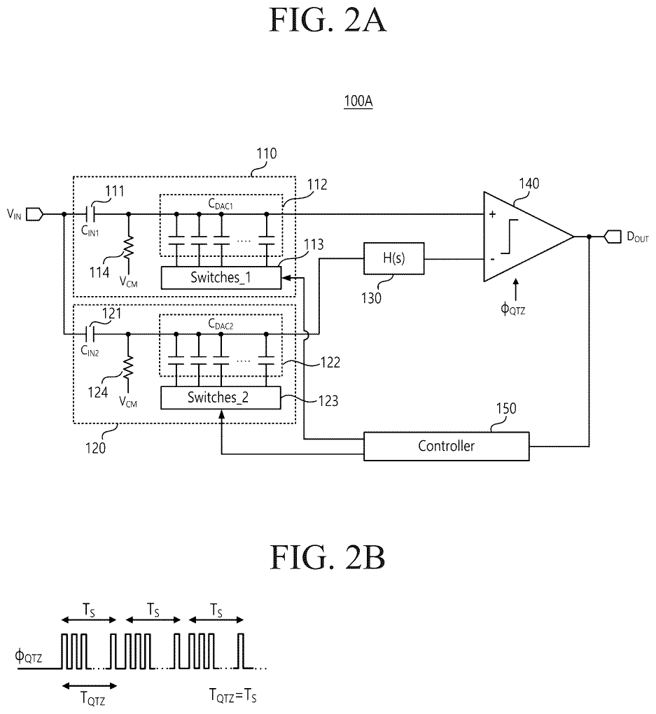

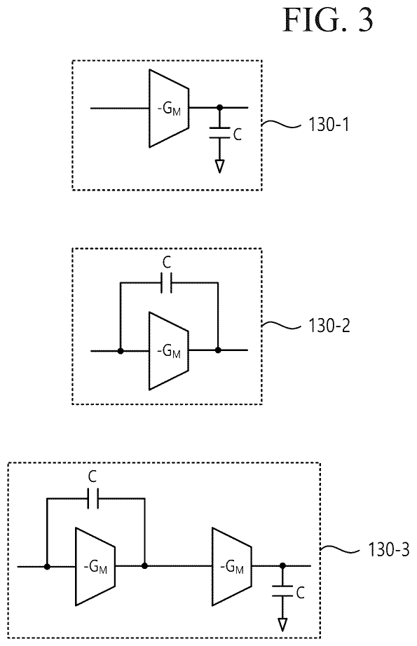

FIG. 2A is a diagram illustrating an implementation example of an analog-to-digital converter according to an example embodiment, and FIG. 2B is a timing diagram illustrating an example of an analog-to-digital conversion cycle of the analog-to-digital converter of FIG. 2A. FIG. 3 is a diagram illustrating the types of loop filters according to various embodiments. The analog-to-digital converter of FIG. 2A may correspond to the analog-to-digital converter of FIG. 1, and the loop filter of FIG. 3 may correspond to the loop filter 130 of FIG. 1.

Referring to FIG. 2A, the analog-to-digital converter 100A may include a first input unit 110, a second input unit 120, a loop filter 130, a comparator 140, and a controller 150.

According to an example embodiment, each of the first input unit 110 and the second input unit 120 may be implemented as a capacitively-coupled input terminal. Referring to FIG. 2A, the first input unit 110 may include a first input capacitor 111 to which an input signal V_{IN} is applied, a first capacitor digital-to-analog converter (CDAC) 112, and a plurality of first switches 113 controlling an operation of the first CDAC 112. The second input unit 120 may include a second input capacitor 121 to which the input signal V_{IN} is applied, a second CDAC 122 connected to the second input capacitor 121, and a plurality of switches 123 controlling an operation of the CDAC 122.

The first CDAC 112 may quantize the input signal V_{IN} based on operations of the plurality of first switches 113. According to an example embodiment, the first CDAC may quantize the input signal V_{IN} using a successive approximation scheme, and may provide the quantized input signal to the comparator 140. The second CDAC 122 may generate a residue signal based on the operations of the plurality of second switches 123. According to an example embodiment, the second CDAC 122 may generate a residue signal corresponding to a difference between the input signal V_{IN} and a previous digital value, and may provide the generated residue signal to the loop filter 130. The configurations of the first CDAC 112 and the second CDAC 122 are not limited to those illustrated in FIG. 2A. According to example embodiments, each of the first CDAC 112 and the second CDAC 122 may be configured in any other way, such a configuration including a split capacitor.

According to an example embodiment, the first input unit 110 may include a resistor 114 to which a DC bias V_{CM} is applied and the second input unit 120 may include a resistor 124 to which a DC bias V_{CM} is applied, as illustrated in FIG. 2A. However, example embodiments are not limited thereto. In some embodiments, the first input unit 110 and the second input unit 120 may not include the resistors 114 and 124. Each of the resistors 114 and 124 may be a pseudo-resistor, but example embodiments are not limited thereto.

The loop filter 130 may integrate the residue signal provided from the second input unit 120. Referring to FIG. 3, the loop filter 130 may be variously implemented as, for example, a GM-C integrator 130-1, a capacitively-coupled instrumentation amplifier (CCIA) 130-2, or a circuit 130-3 in which a GM-C integrator and a CCIA are combined with each other.

The comparator 140 may output a digital value D_{OUT} in units of bits based on the quantized input signal provided from the first input unit 110 and the integrated residue signal provided from the loop filter 130. In this case, according to an example embodiment, the quantized input signal and the integrated residue signal may be continuous signals provided continuously without an additional sampling operation. The quantized input signal and the integrated residue signal may be added in the comparator 140. The comparator 140 may convert the added signal into a corresponding digital value based on a ϕ_{QTZ} signal, and may output the digital value in units of bits.

The controller 150 may control operations of the first input unit 110 and the second input unit 120 based on the output of the comparator 140.

For example, the controller 150 may control the operations of the plurality of first switches 113 to quantize the input signal V_{IN} through the first CDAC 112 in a successive approximation scheme. Accordingly, the first CDAC 112 may continuously track the input signal V_{IN} based on a reference voltage. The quantization of the input signal V_{IN} may be continuously performed during the tracking process.

Also, the controller 150 may apply the previous digital value to a plurality of second switches 123 to generate a residue signal through the second CDAC 122. The residue signal may correspond to a difference between the input signal V_{IN} and the digitalized input signal (for example, the previous digital value). For example, when the previous digital value is applied through the plurality of second switches 123, the second CDAC 122 may generate an analog voltage corresponding to the previous digital value. Accordingly, the second CDAC 122 may generate a residue signal corresponding to a difference between the input signal V_{IN}, applied through the second input capacitor 121, and the analog voltage corresponding to the previous digital value.

In this case, the controller 150 may control the first and second input units 110 and 120 to simultaneously perform the quantization operation and the residue signal generation operation in parallel. Accordingly, according to an example embodiment, a residue signal may be generated and integrated while the input signal V_{IN} is quantized.

According to an example embodiment, the controller 150 may be a SAR logic for performing an analog-to-digital conversion operation in a successive approximation scheme, but example embodiments are not limited thereto.

Referring to FIG. 2B, an analog-to-digital conversion cycle T_{S} of the analog-to-digital converter 100A is illustrated. As described above, the analog-to-digital converter 110A may simultaneously perform a quantization operation and a residue signal integration operation in parallel. Therefore, according to example embodiments, additional time is not required to perform a residual time integration operation, so that a sampling rate of the analog-to-digital converter 100A may be determined by quantization operation time. For example, the analog-to-digital conversion cycle T_{S} and quantization operation time T_{QTZ} may be the same, as illustrated in FIG. 2B. Thus, a higher sampling rate and a wider bandwidth may be achieved.

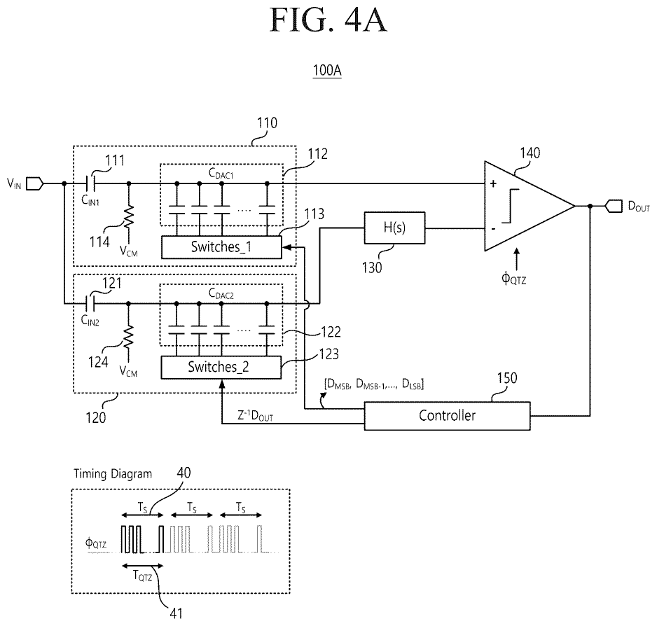

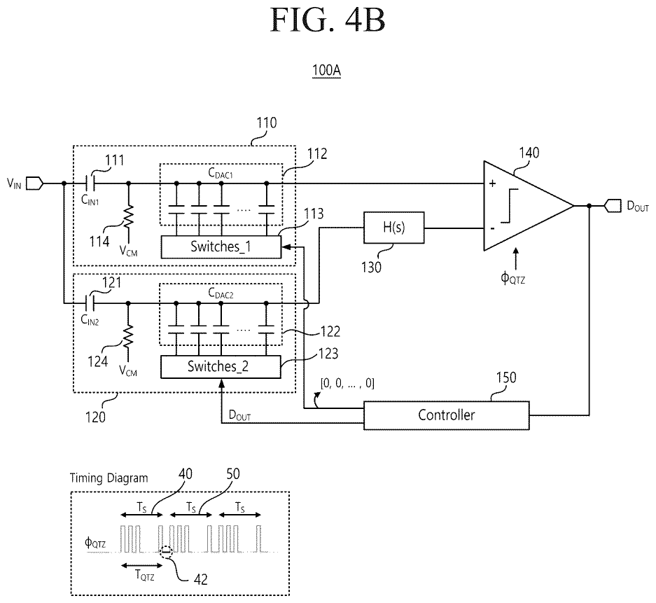

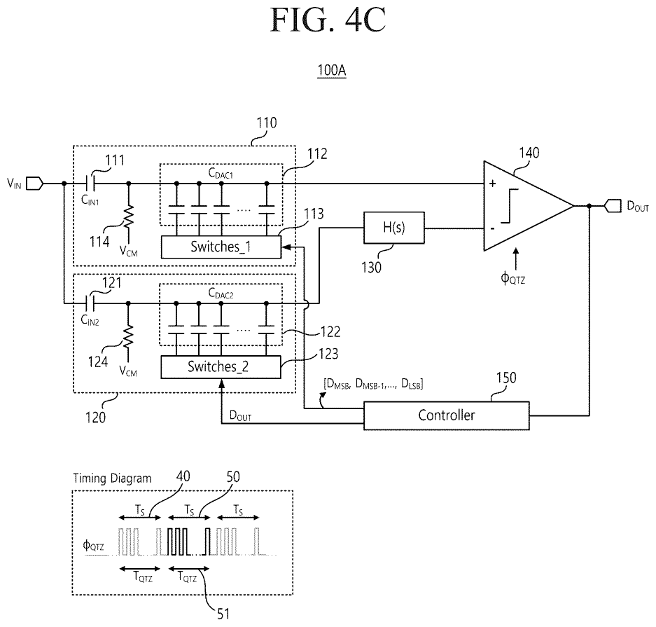

FIGS. 4A to 4C are diagrams illustrating operations of an analog-to-digital converter 100A according to an example embodiment. For example, FIGS. 4A and 4B illustrate operations of the analog-to-digital converter 100A in a quantization operation period 41 and a reset operation period 42, respectively.

Referring to FIG. 4A, a controller 150 may control operations of a plurality of first switches 113 to quantize an input signal V_{IN} through the first CDAC 112 in a successive approximation scheme during the quantization operation period 41. The operations of the plurality of first switches 113 may be controlled based on an output of the comparator 140.

For example, when the quantized input signal and the integrated residue signal are input to the comparator 140, the comparator 140 may compare the two input signals with each other to output a digitized signal D_{OUT}. The controller 150 may generate switch control signals [D_{MSB}, D_{MSB-1} to D_{LSB}] based on the output value D_{OUT} of the comparator 140, and may provide the generated switch control signals to the plurality of first switches 113.

During the quantization operation period 41, the comparator 140 may digitalize the quantized input signal and the integrated residue signal together to output a digital value D_{OUT} in units of bits. Accordingly, the controller 150 may control the plurality of first switches 113 based on the output of comparator, output in units of bits, to find a digital value using a successive approximation scheme.

The controller 150 may apply a previous digital value Z⁻¹D_{OUT} to the plurality of second switches 123 to generate a residue signal through the second CDAC 122 during the quantization operation period 41. Accordingly, the second CDAC 122 may generate a residue signal corresponding to a difference between the input signal V_{IN} and the previous digital value Z⁻¹D_{OUT}. The residue signal may be input to the loop filter 130 to be integrated, and the integrated residue signal may be immediately reflected in the comparator 140. According to an example embodiment, the residue signal generated in the second input unit 120 during the quantization operation period 41 may be continuously applied to the loop filter 130. In addition, the residue signal integrated in the loop filter 130 may be continuously input to the comparator 140 together with the quantized input signal.

When digital values corresponding to the input signal VIN are all obtained from MSB to LSB through the above-described operation, the quantization operation period 41 may end and a reset operation period 42 may start.

During the reset operation period 42, the controller 150 may reset the plurality of first switches 113 and may update the digital value D_{OUT}, obtained in the current analog-to-digital conversion cycle 40, in the plurality of second switches 123.

Referring to FIG. 4B, the controller 150 may reset all of the plurality of first switches 113 during the reset operation period 42 to perform the quantization operation on an input signal V_{IN} applied to the next analog-to-digital conversion cycle 50. In the drawing, [0, 0 to 0] indicate that the controller 150 resets all of the plurality of first switches 113.

During the reset operation period 42, the controller 150 may apply the digital value D_{OUT}, obtained in the current analog-to-digital conversion cycle 40, to the plurality of second switches 123. Accordingly, the second CDAC 122 may generate a residue signal based on the input signal V_{IN} and the digital value D_{OUT} input currently.

FIG. 4C illustrates an operation of the analog-to-digital converter 100A in the quantization operation period of the next analog-to-digital conversion cycle. When the above-described reset operation period 42 and the quantization operation period 51 of the next conversion cycle 50 starts, the quantization operation on the input signal V_{IN} and the generation/integration operation of the residue signal be performed again. In this case, the operation of the analog-to-digital converter 100A in the quantization operation period 51 is the same as described above with reference to FIG. 4A except that the residue signal is generated/integrated based on the digital value DOUT, and thus redundant descriptions will be omitted.

The analog-to-digital converter 100A may continuously and repeatedly perform the above operations and may continuously output digital values.

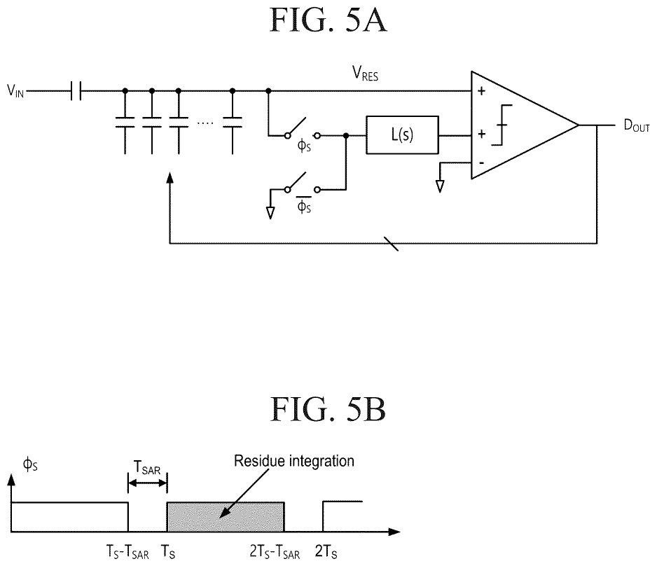

FIGS. 5A and 5B are diagrams illustrating an operation of an analog-to-digital converter according to an example embodiment by comparison with an operation of a general successive approximation register analog-to-digital converter. FIGS. 5A and 5B illustrate an example of a configuration and an operation timing of a general noise shaping (NS) successive approximation register (SAR) analog-to-digital converter operating based on continuous time.

A general successive approximation register analog-to-digital converter operating based on discrete time may inevitably involve an operation of sampling an input signal to a sampling capacitor CS. In this case, kT/Cs noise may be generated during the operation of sampling the input signal, and an analog-to-digital converter requiring higher resolution may require a higher CS value. In addition, as the successive approximation register analog-to-digital converter operates at a high rate, the time required for a sample operation may be reduced, and an input should be settled within a given short time. The above-mentioned limitations may cause an issue in which requirements for an input buffer (power consumption, a design area, or the like) are significantly increased. To address such an issue, a continuous time successive approximation register analog-to-digital converter (ADC) operating based on continuous time without sampling an input signal has been developed.

However, in the case of a general SAR ADC operating based on continuous time, quantization is performed without sampling an input signal. Therefore, when the input signal is not sufficiently slow or an analog-to-digital conversion rate is not high, an error E_{IN} caused by a change in input signal may occur in addition to quantization noise E_{Q}. Unlike the quantization noise E_{Q}, the error E_{IN} may be increased as a high-frequency input signal is applied. When the high-frequency input signal is processed, a resolution of the analog-to-digital converter may be significantly decreased.

As described above, the general SAR ADC operating based on continuous time is appropriate for processing of an input signal of a low frequency band, so that a magnitude of the error E_{IN} may be reduced using noise shaping NS and oversampling.

A more detailed description will be provided with reference to FIGS. 5A and 5B. In the case of, the general NS SAR ADC 55, an input of the loop filter L(s) should be input during a quantization operation period TSAR in which an analog signal is converted into a digital signal. In this case, as a time for which the loop filter L(s) is virtually grounded is increased, a resolution and a signal transmission function may be significantly reduced, so that a quantization operation should be performed in as short a time as possible. Accordingly, in the case of the general NS SAR ADC 55, the higher the sampling rate, the greater an effect on stabilization, and thus the sampling rate may be limited. For example, in the case of the general NS SAR ADC 55, a single cycle time T_{S} should be sufficiently greater than the quantization operation period Torz, so that the sampling rate is limited. For example, in the case of the general NS SAR ADC 55, T_{QTZ}=0.05 T_{S}.

In contrast, the analog-to-digital converter 100 according to example embodiments may operate based on continuous time and may simultaneously perform a quantization operation and a residue signal integration operation in parallel. Accordingly, the analog-to-digital conversion cycle T_{S} and the quantization operation time T_{QTZ} may be the same. As a result, a higher sampling rate and a wider bandwidth may be achieved. In addition, a requirement for the input buffer (power consumption, or the like) may be relaxed and a high resolution may be achieved.

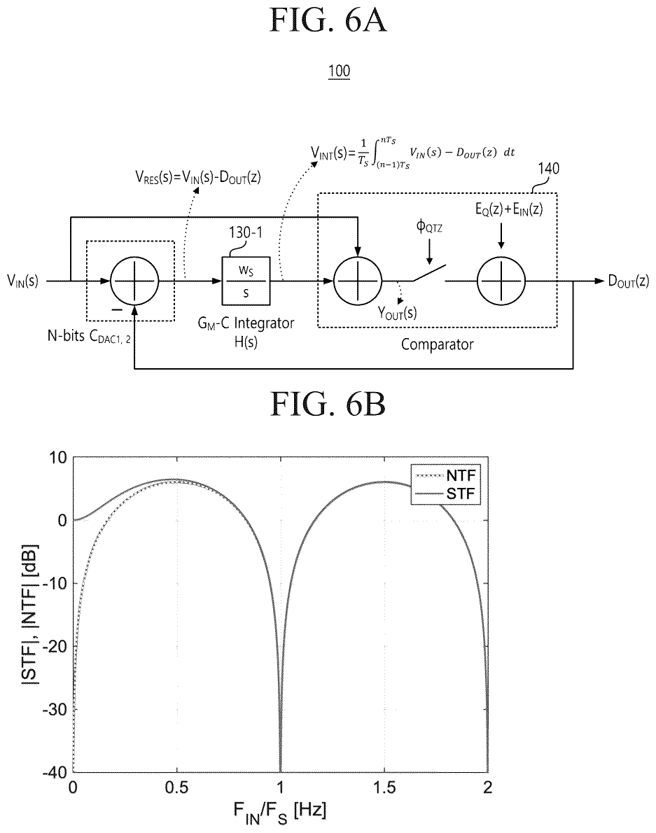

FIG. 6A is a block diagram of an analog-to-digital converter according to an example embodiment. In the drawing, V_{RES(s)} represents a residue signal, for example, a difference between a current input V_{IN(s)} and a digital output D_{OUT}(z), and V_{INT}(s) represents a residue signal value integrated after passing through a GM-C integrator 130-1. The GM-C integrator may be expressed as w_{S}/s in an s-domain. In this case, w_{S} (=1/T_{S}) represents a sampling frequency.

Referring to FIG. 6A, a comparator 140 may output D_{OUT} (z) in a serial operation based on continuous time depending on a signal ϕ_{QTZ}. Such a serial processing operation may cause an error E_{IN}(z) based on a change in the input signal V_{IN}(s) in addition to quantization noise E_{Q}(z).

However, the analog-to-digital converter 100 has first-order noise transfer characteristics, so that E_{IN}(z) may be sufficiently attenuated, which is solved by the following equations.

For example, referring to FIG. 6A, the current input V_{IN}(s) and an integrated residue signal V_{INT}(s) are added in the comparator 140 to be Y_{OUT}(s). This is expressed by the following equation 1.

$${Y}_{O U T} ( s ) = \frac{1}{{T}_{S}} {\int }_{( n - 1 ) {T}_{S}}^{{nT}_{S}} {V}_{IN} ( s ) - {D}_{O U T} ( z ) d t + {V}_{IN} ( s ) \qquad Equation ( 1 )$$

Y_{OUT}(s), a continuous signal, is changed to Your (z), a discrete signal, in the comparator 140 depending on the signal ϕ_{QTZ}. When Y_{OUT}(s) is z-transformed, Y_{OUT}(z) may be obtained as illustrated in the following equation 2.

$${Y}_{O U T} ( z ) = \frac{1 + j 2 π f}{j 2 π f} {V}_{IN} ( z ) - \frac{{z}^{- 1}}{1 - {z}^{- 1}} {D}_{O U T} ( z ) \qquad Equation ( 2 )$$

Then, the quantization noise E_{Q}(z) and the error E_{IN}(z) caused by a change in input are added in the comparator 140, and a final output D_{OUT} (z) may be expressed by the following equation 3.

$${D}_{O U T} ( z ) = \frac{1 + j 2 π f}{j 2 π f} {V}_{IN} ( z ) - \frac{{z}^{- 1}}{1 - {z}^{- 1}} {D}_{O U T} ( z ) + {E}_{Q} ( z ) + {E}_{IN} ( z ) \qquad Equation 3$$

The equation 3 is summarized for D_{OUT} (z) to obtain the following equation 4.

$${D}_{O U T} ( z ) = \frac{1 + j 2 π f}{j 2 π f} ( 1 - {z}^{- 1} ) {V}_{IN} ( z ) + ( 1 - {z}^{- 1} ) ( {E}_{Q} ( z ) + {E}_{IN} ( z ) ) \qquad Equation 4$$

From Equation 4, it can be seen that the analog-to-digital converter 100 exhibits first-order high-band noise transfer characteristics for the quantization noise E_{Q}(z) and the error E_{IN}(z) based on a change in input and exhibits first-order low-band signal transfer characteristics for the input signal V_{IN}(z).

FIG. 6B is a graph illustrating signal transfer characteristics and noise transfer characteristics of an analog-to-digital converter according to an example embodiment. In FIG. 6B, a horizontal axis represents a ratio of a sampling frequency F_{S} to an input signal frequency F_{IN}, and a vertical axis represents absolute values of a signal transfer function (STF) and a noise transfer function (NTF).

From the graph of FIG. 6B, it can be seen that the analog-to-digital converter 100 according to an example embodiment has an anti-aliasing filter function, a first-order low-band signal transfer characteristic for an input signal.

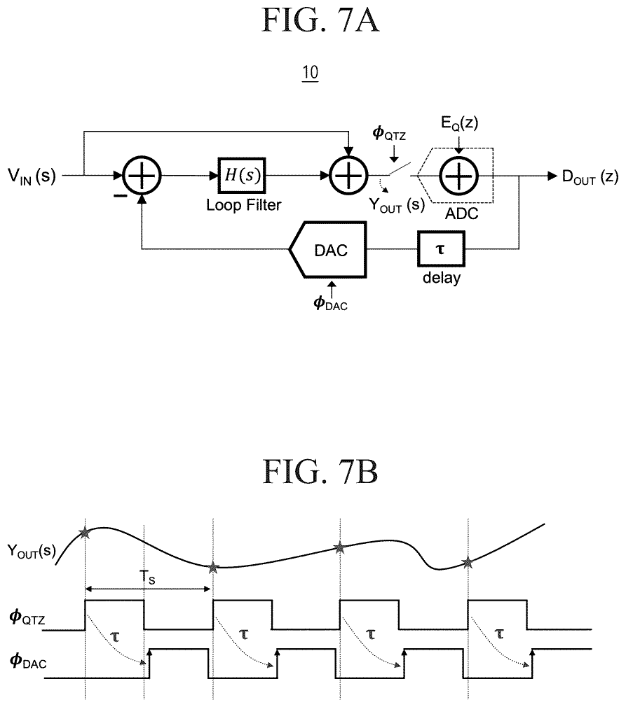

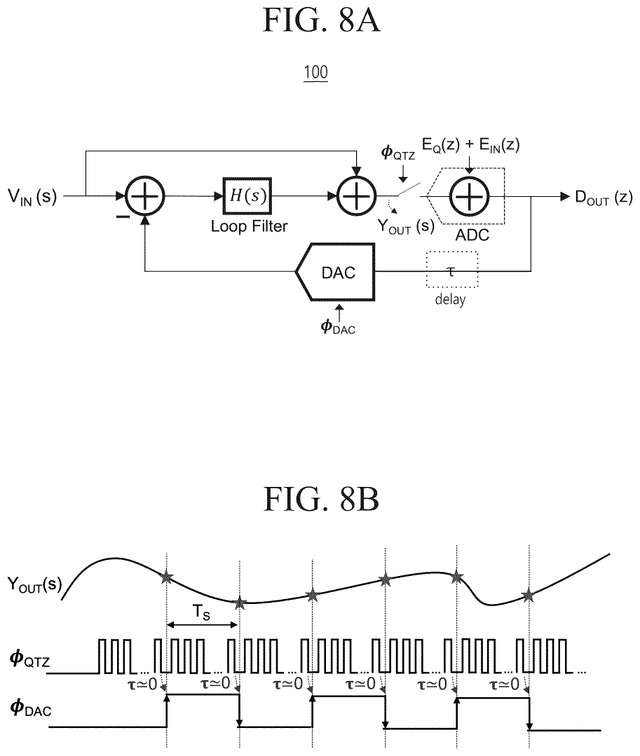

Hereinafter, effects of the present disclosure, associated with excess loop delay, will be described with reference to FIGS. 7A to 8B.

FIGS. 7A and 7B are a block diagram and an operation timing diagram when an analog-to-digital converter operating based on discrete time is applied to a continuous-time delta-sigma modulator, respectively.

Referring to FIGS. 7A and 7B, an analog-to-digital converter 10 operating based on discrete time may sample Y_{OUT}(s), an analog signal, and may then generate a digital signal based on the sampled signal. In this case, the analog-to-digital converter 10 operating based on the discrete time requires a predetermined amount of time until the sampled signal is converted into a digital signal. Accordingly, the digital output signal D_{OUT} (z) may correspond to the signal Y_{OUT}(s) at a time point of being sampled, rather than the signal Y_{OUT}(s) at a time point at which the conversion from the analog signal to the digital signal was finished.

This may cause excess loop delay t. Since the excess loop delay has a significant effect on stability of the analog-to-digital converter, an additional excess loop delay compensation circuit may be required in the case of the analog-to-digital converter 10 operating based on discrete time.

FIGS. 8A and 8B are a block diagram and an operation timing diagram of an analog-to-digital converter according to an example embodiment, respectively. According to an example embodiment, the analog-to-digital converter 100 may be a noise-shaping successive approximation register analog-to-digital converter operating based on continuous time. Accordingly, the analog-to-digital converter 100 has a structure in which an analog-to-digital converter operating based on continuous time is applied to a continuous-time delta-sigma modulator.

Referring to FIG. 8B, the analog-to-digital converter 100 may continuously output digital signals from MSB to LSB for a changed Y_{OUT}(s) without sampling Y_{OUT}(s), unlike FIG. 7B. For example, unlike the case of FIGS. 7A and 7B, a digital output signal D_{OUT} (z) of the analog-to-digital converter 100 may correspond to a value of Y_{OUT}(s) at a time point at which conversion from the analog signal to the digital signal was finished. Accordingly, excess loop delay does not occur during an operation of the analog-to-digital converter 100. As a result, the analog-to-digital converter 100 according to an example embodiment has a significant advantage that an excess loop delay compensation circuit is not required.

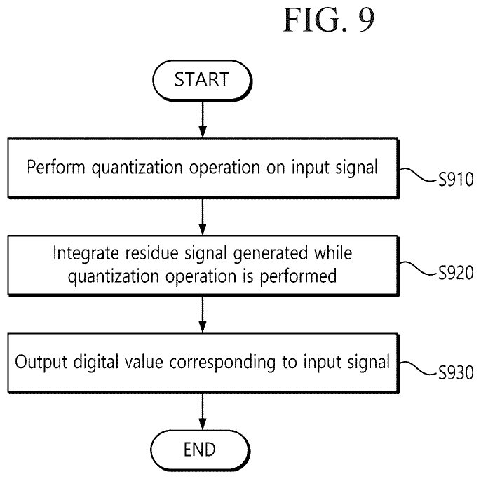

FIG. 9 is a flowchart illustrating a method of operating an analog-to-digital converter according to an example embodiment. In the description provided with reference to FIG. 9, any redundant details will be omitted or simplified.

Referring to FIG. 9, in operation S910, the analog-to-digital converter 100 may perform a quantization operation on an input signal in a successive approximation scheme.

For example, the analog-to-digital converter 100 may include a first input unit 110 and a second input unit 120, each to which an input signal is applied. Accordingly, the analog-to-digital converter 100 may perform a quantization operation based on the input signal applied through the first input unit 100. The input signal may be a continuous analog signal applied to each of the first and second input units 110 and 120 without an additional sampling operation.

In operation S920, the analog-to-digital converter 100 may integrate a residue signal generated during the quantization operation. For example, the analog-to-digital converter 100 may generate a residue signal based on the input signal applied through the second input unit 120, and may integrate the generated residue signal. The residue signal may correspond to a difference between an input signal and a previous digital value output during a previous analog-to-digital conversion cycle.

In operation S930, the analog-to-digital converter 100 may output a digital value corresponding to the input signal based on the input signal quantized through the quantization operation and the integrated residue signal. According to an example embodiment, the analog-to-digital converter 100 may output a digital value corresponding to an input signal in units of bits.

According to an example embodiment, the first input unit 110 may include a first input capacitor 111 to which an input signal is applied, a first CDAC 112 connected to the first input capacitor 111, a plurality of first switches 113 controlling an operation of the CDAC 112. In addition, the second input unit 120 may include a second input capacitor 121 to which an input signal is applied, the second CDAC 122 connected to the second input capacitor 121, and a plurality of second switches 123 controlling an operation of the second CDAC 122.

Accordingly, the analog-to-digital converter 100 may control operations of the plurality of first switches 113 based on the digital values output in units of bits to quantize an input signal in a successive approximation scheme. Also, the analog-to-digital converter 100 may generate apply a previous digital value to the plurality of second switches 123 to generate a residue signal while the quantization operation is performed.

The analog-to-digital converter 100 may reset the plurality of first switches 113 when all digital values corresponding to the input signals are output in units of bits, and may apply the digital values corresponding to the input signals to the second input unit 120.

For ease of description, the analog-to-digital converter 100A having a single input structure has been described as an example. However, example embodiments are not limited thereto. For example, the above-described contents may also be applied to an analog-to-digital converter having a differential input structure.

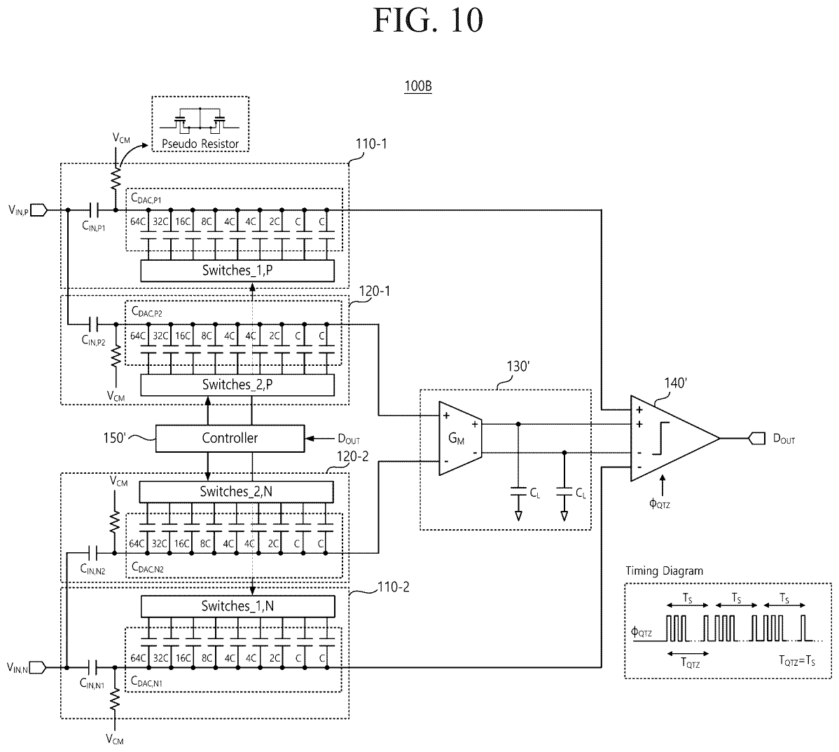

FIG. 10 is a diagram illustrating an implementation example of an analog-to-digital converter having a differential input structure according to an example embodiment. In the description provided with reference to FIG. 10, the same contents as described above or contents obvious from the above description will be omitted.

Referring to FIG. 10, an analog-to-digital converter 100B may include a first differential input unit 110-1, quantizing a first input signal V_{IN,P} included in a differential input signal, and a second differential input unit 110-2 quantizing a second input signal V_{IN,N}.

Also, the analog-to-digital converter 100B may include a third differential input unit 120-1, generating a first residue signal corresponding to a difference between the first input signal V_{IN,P} and a previous digital value, and a fourth differential input unit 120-2 generating a second residue signal corresponding to a difference between the second input signal V_{IN,N} and a previous digital value.

Also, the analog-to-digital converter 100B includes a loop filter 130 generating a residue signal. In this case, the loop filter 130 may integrate the first and second residue signals, respectively applied from the third and fourth differential input units 120-1 and 120-2, and may apply the integrated residue signals to a comparator 140′.

Accordingly, the comparator 140′ may output a digital value corresponding to the differential input signal in units of bits based on the quantized first and second input signals and the integrated first and second residue signals.

A controller 150′ may apply the previous digital values to the third and fourth input units 120-1 to generate the first and second residue signals during the quantization of the first and second input signals, respectively. In addition, the controller 150′ may control the first and second differential input units 110-1 and 110-2 to respectively quantize the first and second input signals in a successive approximation scheme based on an output of the comparator 140′.

According to an example embodiment, a redundancy capacitor may be added to each of the CDACs included in the input unit 110, 120, 110-1, 110-2, 120-1, and 120-2 to further increase a bandwidth.

Referring to FIG. 10, each of the CDACs (CDAC, P1, CDAC, N1, CDAC, P2, CDAC, and N2) included in the first differential input unit 110-1, the second differential input unit 110-2, the third differential input unit 120-1, and the fourth differential input unit 120-2 may include a redundancy capacitor 4C. In this case, a bandwidth of the analog-to-digital converter 100B may be additionally increased.

In FIG. 10, the case in which the capacitor 4C is added as a redundancy capacitor has been described as an example, but example embodiments are not limited thereto. It will be appreciated that one or more other capacitors may be added as a redundancy capacitor. In addition, in FIG. 10, an example of adding a redundancy capacitor to a CDAC of the analog-to-digital converter 100B having a differential input structure has been described, but example embodiments are not limited thereto. In addition, it will be appreciated that a redundancy capacitor may also be added to the CDAC of the above-described analog-to-digital converter 100A having a single input structure to increase a bandwidth.

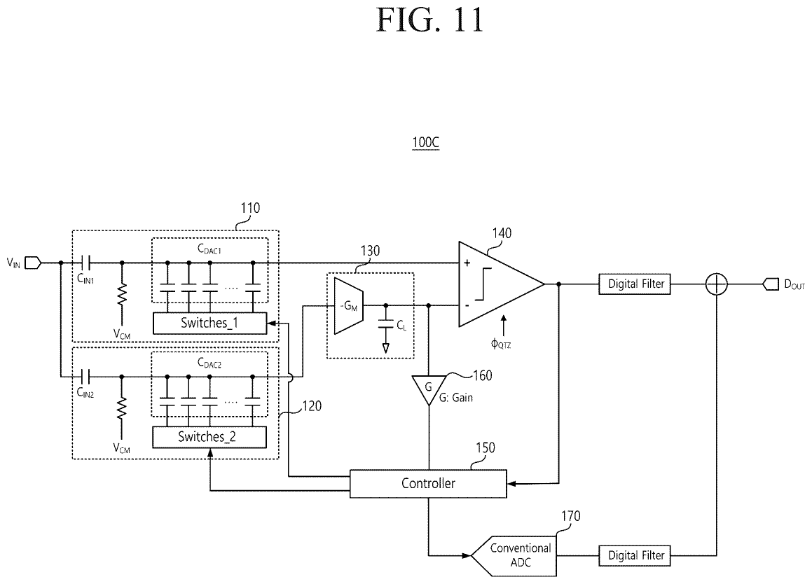

FIG. 11 is a diagram illustrating an implementation example of an analog-to-digital converter according to an example embodiment. Referring to FIG. 11, an analog-to-digital converter 100C may be an analog-to-digital converter having a pipeline structure including a plurality of stages.

For example, according to an example embodiment, the above-descried analog-to-digital converter 100 may be mixed with a general pipeline structure to further increase a resolution. In this case, referring to FIG. 11, a general amplifier may be used in a gain portion (G) 160. In addition, a flash ADC, a successive approximation register ADC, or a noise-shaping successive approximation register ADC may be variously used in an analog-to-digital converter 170 according to the related art.

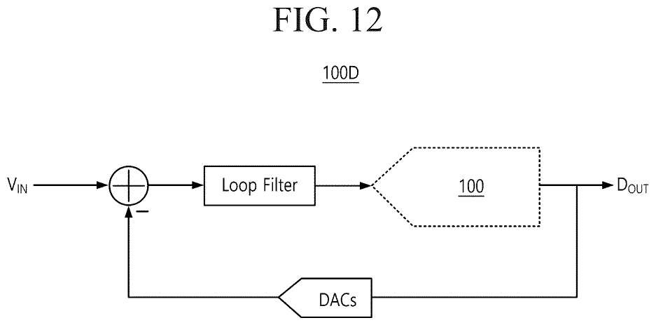

FIG. 12 is a diagram illustrating an implementation example of an analog-to-digital converter according to an example embodiment. Referring to FIG. 12, an analog-to-digital converter 100D may have a structure in which the above-described analog-to-digital converter 100 is included in a delta-sigma modulator having a nested structure. For example, the above-described analog-to-digital converter 100 may be applied to a delta-sigma modulator having a nested structure. Accordingly, a resolution of the analog-to-digital converter 100 may be further increased.

The above-described analog-to-digital converters 100, 100A, 100B, 100C, and 100D according to example embodiments may be used in the fields of wireless communication, a radio-frequency (RF) circuit sensor, or the like, requiring high power efficiency and a high sampling rate. In addition, the above-described input units 110, 120, 110-1, 110-2, 120-1, and 120-2 of the analog-to-digital converters 100, 100A, 100B, 100C, and 100D have high impedance, the analog-to-digital converters 100, 100A, 100B, 100C, and 100D may be various types of biosensors for detecting an electroencephalography (EEG) signal, an electrocardiography (ECG) signal, an electromyography (EMG) signal, or a neural signal. However, example embodiments are not limited thereto.

According to above-described example embodiments, an analog-to-digital converter may achieve a higher sampling rate and a wider bandwidth. In addition, the analog-to-digital converter may achieve high power efficiency and high resolution.

As set forth above, according to example embodiments, an analog-to-digital converter may achieve a higher sampling rate and a wider bandwidth.

Example embodiments have been described above with the aid of method steps illustrating the performance of specified functions and relationships thereof. The boundaries and sequence of these functional building blocks and method steps have been defined herein for convenience of description. Alternate boundaries and sequences can be defined, so long as the specified functions and relationships are appropriately performed. Any such alternate boundaries or sequences are thus within the scope and spirit of the claims.

In various example embodiments herein, reference may have been made to various circuit elements, including but not limited to capacitors, resistor, inductors, switches, amplifiers, comparators, filters, and transistors. Various different types of digital, analog, active and/or passive components are available for use in implementing the example embodiments. For example, as discussed above, pseudo-resistors can be substituted for passive resistors. Additionally various different transistor types can be used depending on the implementation, whether positive or negative logic is used, manufacturing processes employed, or the like. Furthermore, unless specifically stated otherwise herein, there are many available types of filters, comparators, switches, and the like that can be used to implement the example embodiments.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While example embodiments have been shown and described above, it will be apparent to those skilled in the art that modifications and variations could be made without departing from the scope of the present inventive concept as defined by the appended claims.

What is claimed is:

1. An analog-to-digital converter comprising:
a first input unit configured to quantize an input signal to generate a quantized input signal;
a second input unit configured to generate a residue signal corresponding to a difference between the input signal and a previous digital value output during a previous analog-to-digital conversion cycle;
a loop filter configured to generate an integrated residue signal;
a comparator configured to output a digital value corresponding to the input signal in units of bits based on the quantized input signal and the integrated residue signal; and
a controller configured to apply the previous digital value to the second input unit such that the residue signal is generated during quantization of the input signal and to control the first input unit such that the input signal is quantized in a successive approximation scheme based on an output of the comparator.

2. The analog-to-digital converter of claim 1, wherein
the first input unit comprises a first input capacitor to which the input signal is applied, a first capacitor digital-to-analog converter (CDAC) connected to the first input capacitor, and a plurality of first switches configured to control an operation of the first CDAC, and
the second input unit comprises a second input capacitor to which the input signal is applied, a second CDAC connected to the second input capacitor, and a plurality of second switches configured to control an operation of the second CDAC.

3. The analog-to-digital converter of claim 2, wherein
the input signal is a continuous analog signal applied to each of the first and second input capacitors without an additional sampling operation.

4. The analog-to-digital converter of claim 3, wherein
an analog-to-digital conversion cycle of the analog-to-digital converter comprises a quantization operation period, in which the input signal is quantized, and a reset operation period in which a next analog-to-digital conversion cycle is prepared,
the residue signal is continuously applied to the loop filter during the quantization operation period, and
the residue signal integrated in the loop filter is continuously input to the comparator, together with the quantized input signal, during the quantization operation period.

5. The analog-to-digital converter of claim 4, wherein
the controller controls the plurality of first switches based on an output of the comparator to quantize the input signal through the first CDAC in the successive approximation scheme during the quantization operation period.

6. The analog-to-digital converter of claim 5, wherein
the controller applies the previous digital value to the plurality of second switches to generate the residue signal through the second CDAC during the quantization operation period.

7. The analog-to-digital converter of claim 6, wherein
the controller resets the plurality of first switches during the reset operation period and applies a digital value, output from the comparator, to the plurality of second switches during the quantization operation period.

8. The analog-to-digital converter of claim 1, wherein
the loop filter comprises at least one of a GM-C integrator, a capacitively-coupled instrumentation amplifier (CCIA), or a circuit in which a GM-C integrator and a CCIA are combined with each other.

9. The analog-to-digital converter of claim 1, wherein
the input signal is a differential input signal comprising a first input signal and a second input signal,
the first input unit comprises a first differential input unit configured to quantize the first input signal and a second differential input unit configured to quantize the second input signal, and
the second input unit comprises a third differential input unit configured to generate a first residue signal corresponding to a difference between the first input signal and the previous digital value and a fourth differential input unit configured to generate a second residue signal corresponding to a difference between the second input signal and the previous digital value.

10. The analog-to-digital converter of claim 9, wherein
the loop filter integrates each of the first and second residue signals,
the comparator outputs a digital value corresponding to the differential input signal in units of bits based on the quantized first and second input signals and the integrated first and second residue signals, and
the controller applies the previous digital value to the third and fourth differential input units, respectively, to generate the first and second residue signals during quantization of the first and second input signals, and controls the first and second differential input units, respectively, to quantize the first and second input signals in a successive approximation scheme based on an output of the comparator.

11. The analog-to-digital converter of claim 2, wherein
each of the first and second CDACs comprises at least one redundancy capacitor.

12. The analog-to-digital converter of claim 1, wherein
the analog-to-digital converter corresponds to a single stage, among a plurality of stages included in an analog-to-digital converter having a pipeline structure.

13. The analog-to-digital converter of claim 1, wherein
the analog-to-digital converter comprises a delta-signal modulator having a nested structure.

14. A method of operating an analog-to-digital converter, the method comprising:
performing a quantization operation on an input signal in a successive approximation scheme;
integrating a residue signal generated while the quantization operation is performed; and
outputting a digital value corresponding to the input signal based on an input signal quantized through the quantization operation and the integrated residue signal,
wherein
the residue signal corresponds to a difference between the input signal and a previous digital value output during a previous analog-to-digital conversion cycle.

15. The method of claim 14, wherein
the analog-to-digital converter comprises a first input unit and a second input unit, each to which the input signal is applied,
the performing the quantization operation comprises
performing the quantization operation based on the input signal applied through the first input unit, and
the integrating the residue signal comprises
generating the residue signal based on the input signal applied through the second input unit, and
integrating the residue signal.

16. The method of claim 15, wherein
the input signal is a continuous analog signal applied to each of the first and second input units without an additional sampling operation.

17. The method of claim 16, wherein
the first input unit comprises a first input capacitor to which the input signal is applied, a first capacitor digital-to-analog converter (CDAC) connected to the first input capacitor, and a plurality of first switches configured to control an operation of the first CDAC, and
the second input unit comprises a second input capacitor to which the input signal is applied, a second CDAC connected to the second input capacitor, and a plurality of second switches configured to control an operation of the second CDAC.

18. The method of claim 17, wherein
the outputting the digital value comprises
outputting a digital value corresponding to the input signal in units of bits,
the performing the quantization operation comprises
controlling operations of the plurality of first switches based on the digital value output in units of bits to quantize the input signal in the successive approximation scheme, and
the generating the residue signal comprises
applying the previous digital value to the plurality of second switches to generate the residue signal while the quantization operation is performed.

19. The method of claim 18, comprising:
resetting the plurality of first switches and applying the digital value corresponding to the input signal to the plurality of second switches when the digital value corresponding to the input signal is output in units of bits.

20. A successive approximation analog-to-digital converter comprising:
a first capacitively-coupled input unit configured to receive an input signal being a continuously changed analog signal and to quantize the input signal in a binary search scheme based on a control signal to generate a quantized input signal;
a second capacitively-coupled input unit configured to receive the input signal and to generate a residue signal corresponding to a difference between the input signal and a previous digital value when the previous digital value is received;
a loop filter configured to integrate the residue signal to generate an integrated residue signal;
a comparator configured to output a digital value corresponding to the input signal in units of bits based on the quantized input signal and the integrated residue signal; and
a successive approximation register logic configured to apply the control signal to the first capacitively-coupled input unit based on an output of the comparator,
wherein
the successive approximation register logic applies the previous digital value, output from the comparator, to the second capacitively-coupled input unit during a previous analog-to-digital conversion cycle.
